(19) United States
(12) Patent Application Publication
(10) Pub. No.: US 2025/0159908 A1
(43) Pub. Date: May 15, 2025

(54) MEMORY DEVICE AND METHOD OF FORMING THE SAME

(71) Applicant: Taiwan Semiconductor Manufacturing Company, Ltd., Hsinchu (TW)

(72) Inventors: Tung-Ying Lee, Hsinchu City (TW); Shao-Ming Yu, Hsinchu County (TW); Xinyu BAO, Fremont, CA (US); Hengyuan Lee, Hsinchu County (TW)

(73) Assignee: Taiwan Semiconductor Manufacturing Company, Ltd., Hsinchu (TW)

(21) Appl. No.: 18/507,100

(22) Filed: Nov. 13, 2023

(51) Int. Cl. H10B 63/00

(52) U.S. Cl. CPC H10B 63/84; H10B 63/24

(57) ABSTRACT

A memory device includes first and second word lines extending in the first direction, a first bit line between the first and second word lines and extending a second direction, first and second word line columns extending in a third direction and disposed on opposing sides of the first bit line, a selector layer lining the first and second sides of the first bit line, and a memory layer lining the selector layer and connected to the first and second word line columns. The first, second, and third directions are different. The first word line column is coupled to the first word line through a first conductive via, the second word line column is coupled to the second word line through a second conductive via, and the first and second conductive vias are offset in the first and third direction.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while the geometry size has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed. For example, a three-dimensional (3D) memory device has been introduced to replace a planar memory device. However, 3D memory device has not been entirely satisfactory in all respects, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit (IC) die with a memory device according to some embodiments.

FIGS. 2A, 3A, 4A, 5A, 6A, 7A, and 8A illustrate schematic plan views of an intermediate step in the manufacture of a memory device, in accordance with some embodiments.

FIGS. 2B-2C, 3B-3C, 4B-4D, 5B-5E, 6B-6E, 7B-7E, and 8B-8E illustrate schematic cross-sectional views of an intermediate step in the manufacture of a memory device, in accordance with some embodiments.

FIG. 8F illustrates a schematic and simplified perspective view of a memory device, in accordance with some embodiments.

FIG. 9A illustrates a schematic plan view of a memory device, in accordance with some embodiments.

FIGS. 9B-9E illustrate schematic cross-sectional views of a memory device, in accordance with some embodiments.

FIG. 9F illustrates a schematic and simplified perspective view of a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

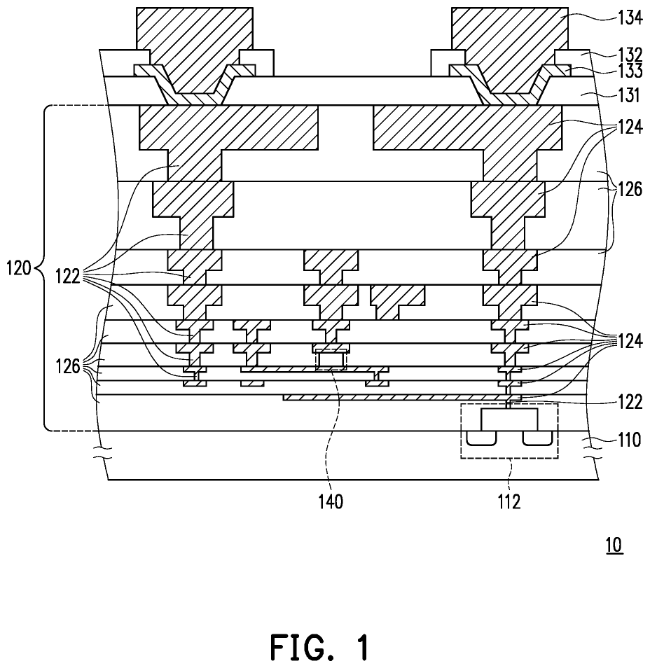

FIG. 1 is a schematic cross-sectional view of an integrated circuit (IC) die with a memory device according to some embodiments. Referring to FIG. 1, an IC die 10 may include a substrate 110, an interconnect structure 120 disposed over the substrate 110, a passivation layer 131 disposed over the interconnect structure 120, a post-passivation layer 132 disposed over the passivation layer 131, conductive pads 133 disposed on and passing through the passivation layer 131 to be electrically connected to the interconnect structure 120, and conductive terminals 134 landing on the conductive pads 133. The substrate 110 may be a semiconductor substrate, such as a bulk semiconductor, a semiconductor-on-insulator (SOI) substrate, a multi-layered substrate, a gradient substrate, or the like. In some embodiments, the semiconductor material of the substrate 110 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Devices, such as active devices (e.g., transistors, diodes, etc.), capacitors, resistors, or the like, may be formed in/on the front side of the substrate 110. The devices are represented by a transistor 112 in the illustrated embodiment. For example, the substrate 110 includes various doped regions doped with p-type dopants or n-type dopants, depending on the circuit requirements. In some embodiments, the doped regions serve as source/drain regions of the transistor 112. Depending on the types of the dopants in the doped regions, the transistor 112 may be referred to as n-type transistor or p-type transistor. In some embodiments, the transistor 112 includes a metal gate located above the substrate 110 and embedded in the interconnect structure 120 and a channel under the metal gate and located between the source/drain regions, where the channel serves as a path for electron to travel when the transistor 112 is turned on. In some embodiments, the transistor 112 is formed using suitable Front-end-of-line (FEOL) process and may be referred to as the FEOL device. For simplicity, one transistor 112 is shown in FIG. 1; however, it should be understood that a plurality of transistors may be formed depending on the application of the IC die 10.

With continued reference to FIG. 1, the interconnect structure 120 may include conductive vias 122, conductive patterns 124, and dielectric layers 126 covering the conductive vias 122 and the conductive patterns 124. The conductive patterns 124 located at different level heights may be physically and electrically connected to one another through the conductive vias 122. In some embodiments, the bottommost conductive vias 122 are connected to the metal gate of the transistor 112 which is embedded in the bottommost dielectric layer 126. It should be noted that in alternative cross-sectional views, other bottommost conductive vias 122 are also connected to source/drain regions of the transistor 112. In some embodiments, the material of the conductive patterns 124 and the conductive vias 122 includes aluminum, titanium, copper, nickel, tungsten, alloys, a combination thereof, etc. In some embodiments, the material of the dielectric layers 126 includes polyimide, benzocyclobutene (BCB), polybenzoxazole (PBO), or any other suitable dielectric material. Alternatively, the dielectric layers 126 may be formed of oxides or nitrides, such as silicon oxide, silicon nitride, or the like. It should be noted that the number of the dielectric layers 126, the number of the conductive patterns 124, and the number of the conductive vias 122 illustrated in FIG. 1 are merely for illustrative purposes and construe no limitation in the disclosure. It should be noted that fewer or more layers of the dielectric layers 126, the conductive patterns 124, and/or the conductive vias 122 may be formed depending on the circuit design.

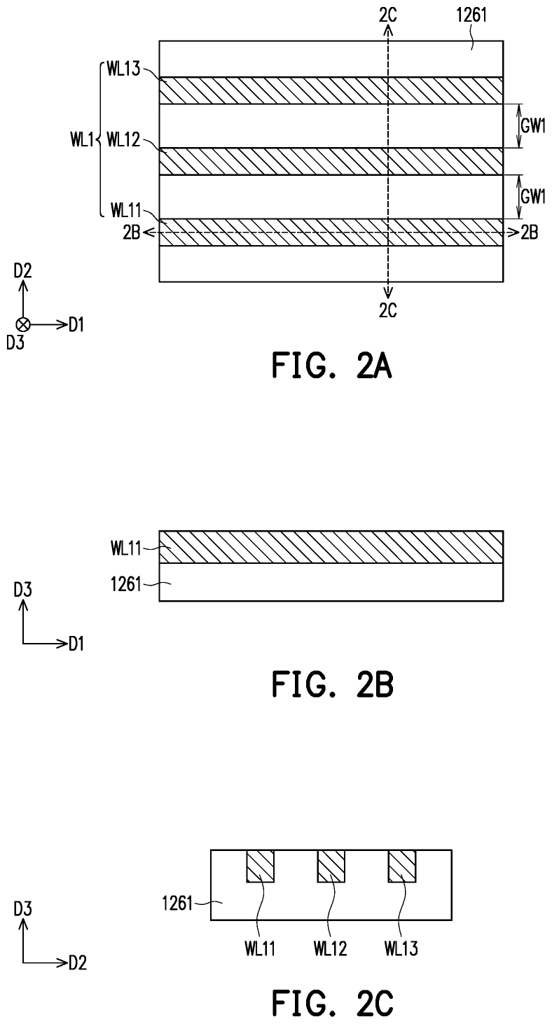

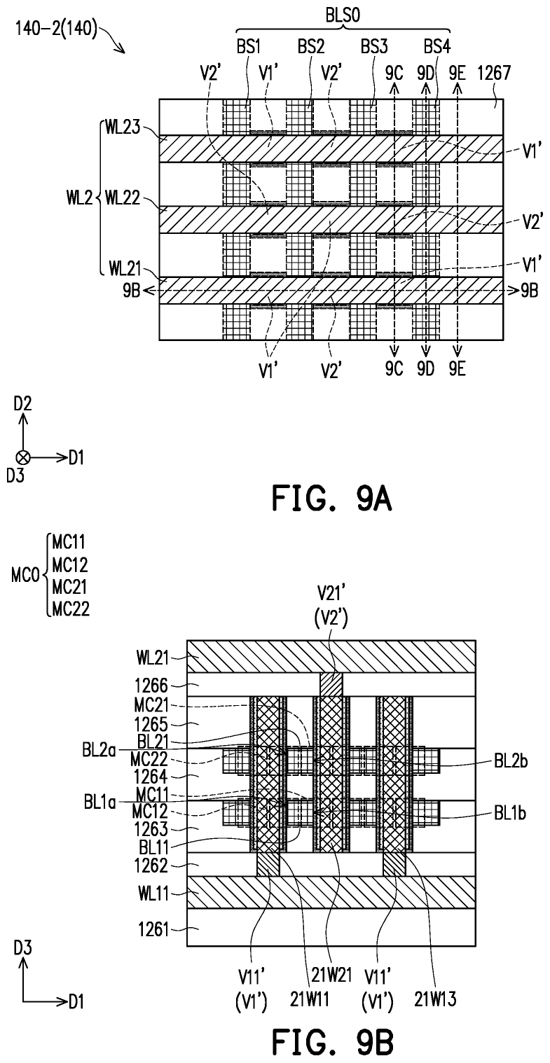

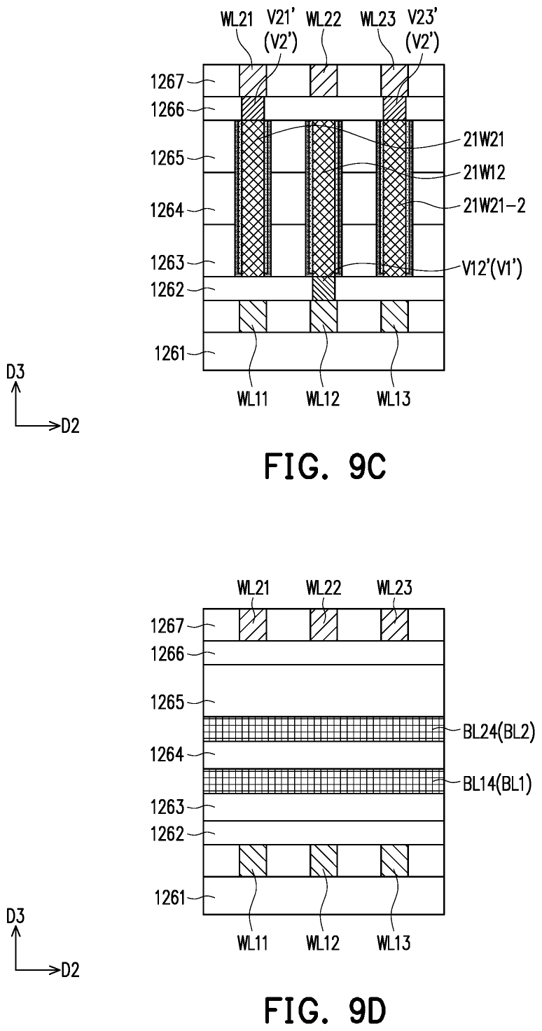

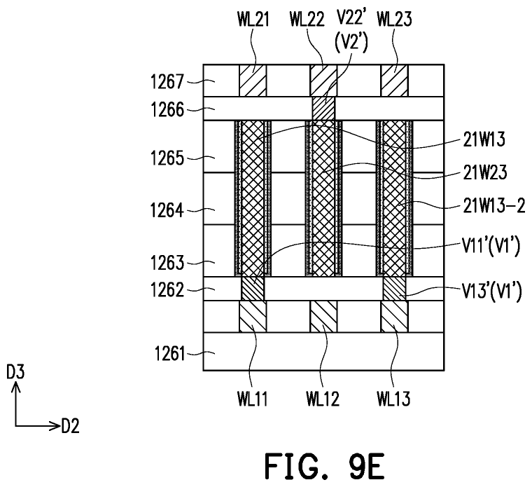

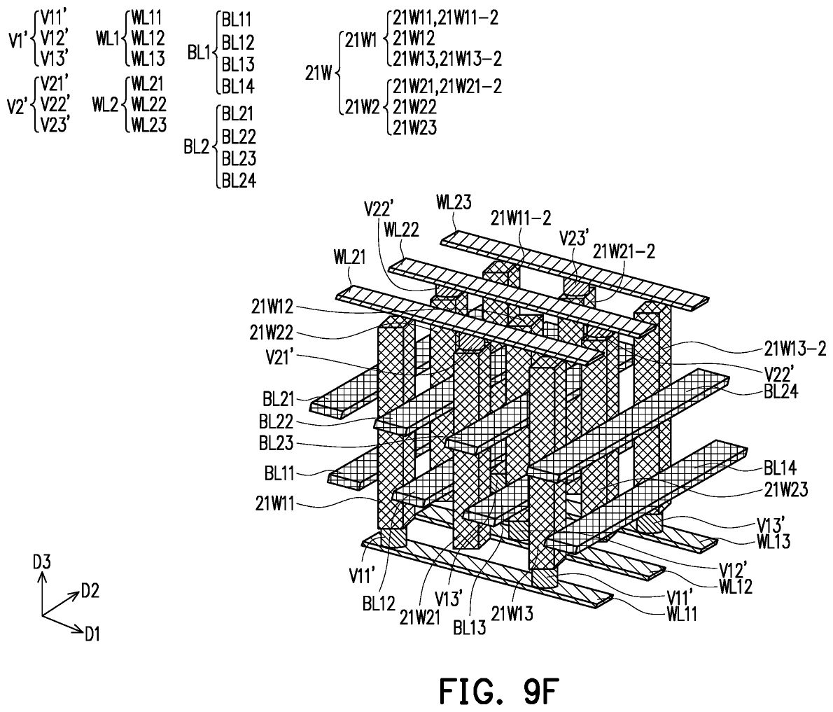

In some embodiments, a memory device 140 (e.g., 140-1 shown in FIGS. 8A-8F or 140-2 shown in FIGS. 9A-9F) is embedded in any level of the interconnection structure 120. For example, the memory device 140 is embedded in one of the dielectric layers 126. In some embodiments, the memory device 140 is formed during back-end-of-line (BEOL) process. Although one memory device 140 is shown in FIG. 1 for the sake of simplicity; however, it should be understood that more than one memory devices 140 may be formed depending on the application of the IC die 10. The memory device 140 may allow for increased memory cell density of the memory array without increasing the area of the memory array. The manufacturing method and the detailed structure of the memory device 140 will be described below in conjunction with FIGS. 2A-9F.

With continued reference to FIG. 1, the passivation layer 131, the conductive pads 133, the post-passivation layer 132, and the conductive terminals 134 are sequentially formed on the interconnect structure 120. In some embodiments, the passivation layer 131 is disposed on the topmost dielectric layer 126 and the topmost conductive patterns 124. In some embodiments, the passivation layer 131 has a plurality of openings partially exposing each topmost conductive pattern 124. In some embodiments, the passivation layer 131 is a silicon oxide layer, a silicon nitride layer, a silicon oxy-nitride layer, or a dielectric layer formed by other suitable dielectric materials. In some embodiments, the conductive pads 133 are formed over the passivation layer 131 and extend into the openings of the passivation layer 131 to be in physical and electrical contact with the topmost conductive patterns 124. In some embodiments, the conductive pads 133 include aluminum pads, copper pads, titanium pads, nickel pads, tungsten pads, or other suitable metal pads. It should be noted that the number and the shape of the conductive pads 133 illustrated in FIG. 1 are merely for illustrative purposes and construe no limitation in the disclosure.

In some embodiments, the post-passivation layer 132 is formed over the passivation layer 131 and the conductive pads 133. In some embodiments, the post-passivation layer 132 has a plurality of contact openings partially exposing each conductive pad 133. The post-passivation layer 132 may be a polyimide layer, a PBO layer, or a dielectric layer formed by other suitable polymers. In some embodiments, the conductive terminals 134 are formed over the post-passivation layer 132 and extend into the contact openings of the post-passivation layer 132 to be in physical and electrical contact with the corresponding conductive pad 133. In some embodiments, the conductive terminals 134 are conductive pillars, conductive posts, conductive balls, conductive bumps, or the like. The conductive terminals 134 may be made of aluminum, titanium, copper, nickel, tungsten, tin, and/or alloys thereof. In some embodiments, the conductive terminals 134 are used to establish electrical connection with other components (not shown) subsequently formed or provided.

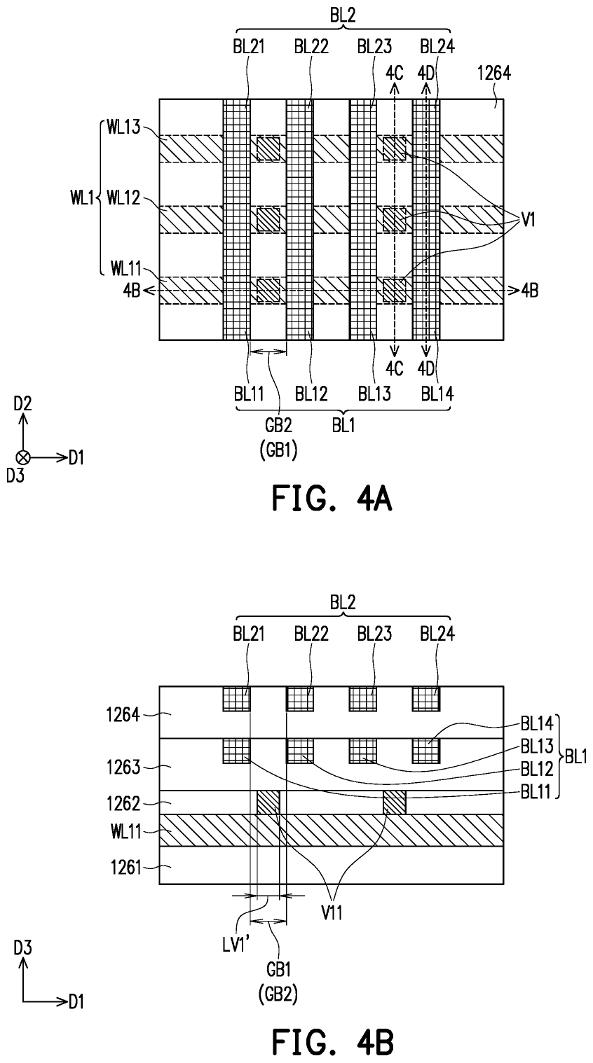

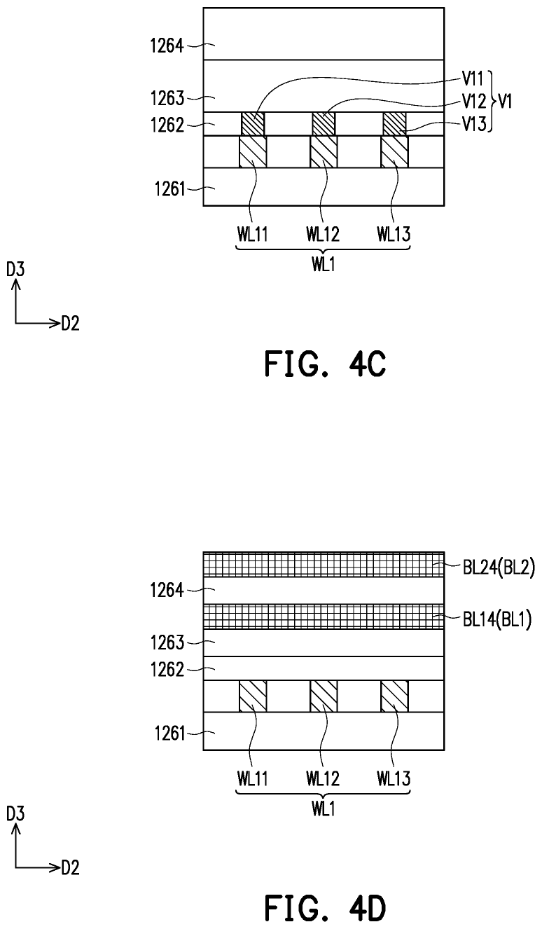

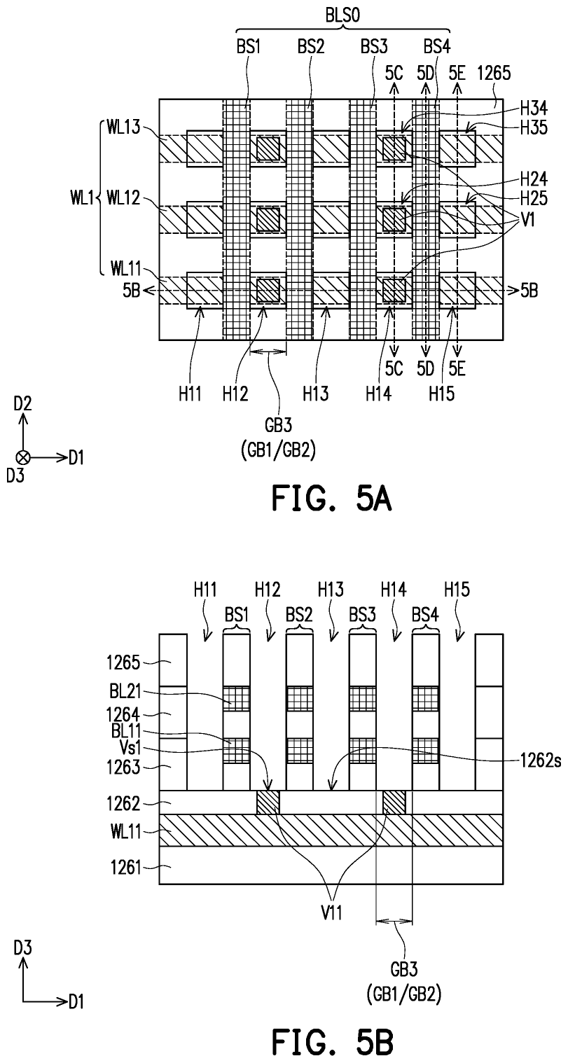

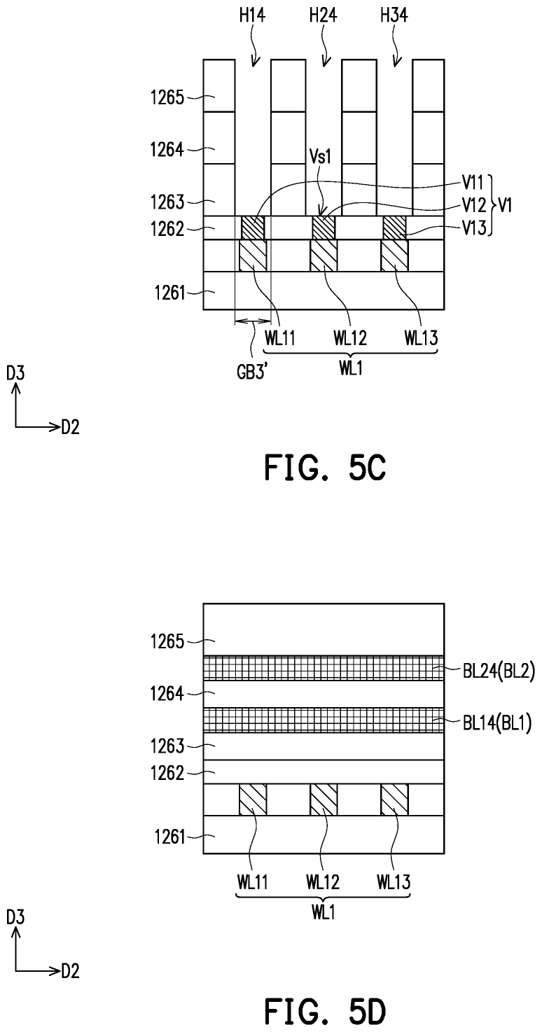

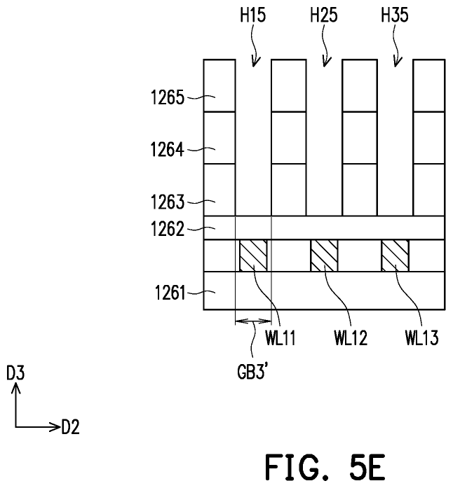

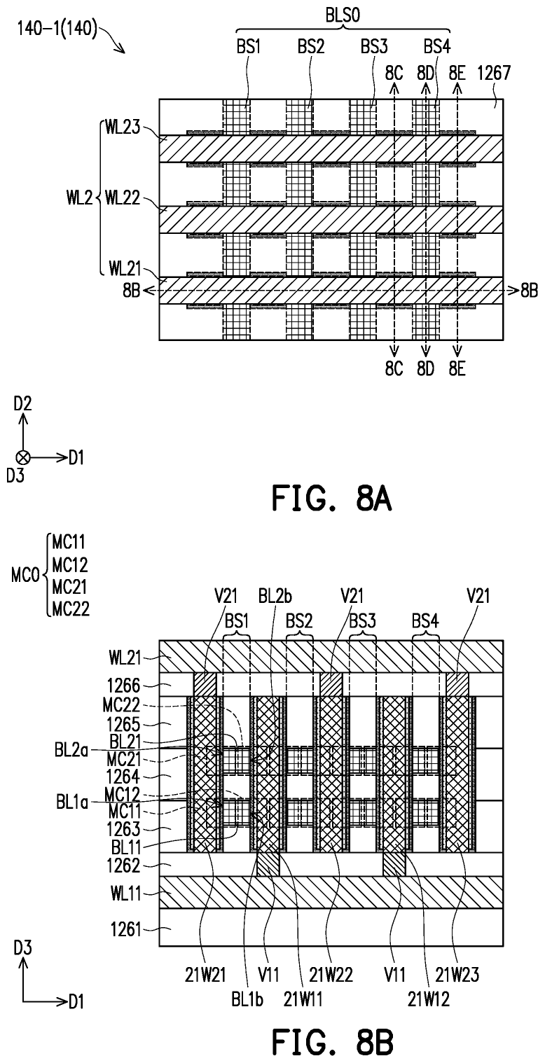

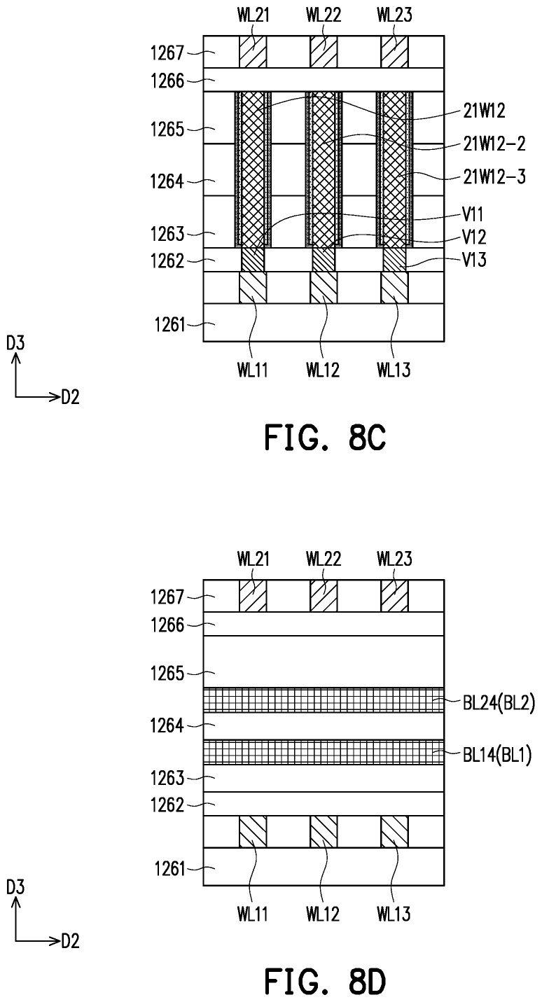

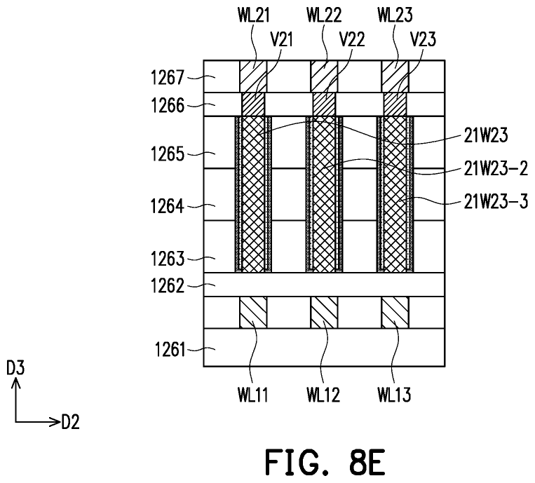

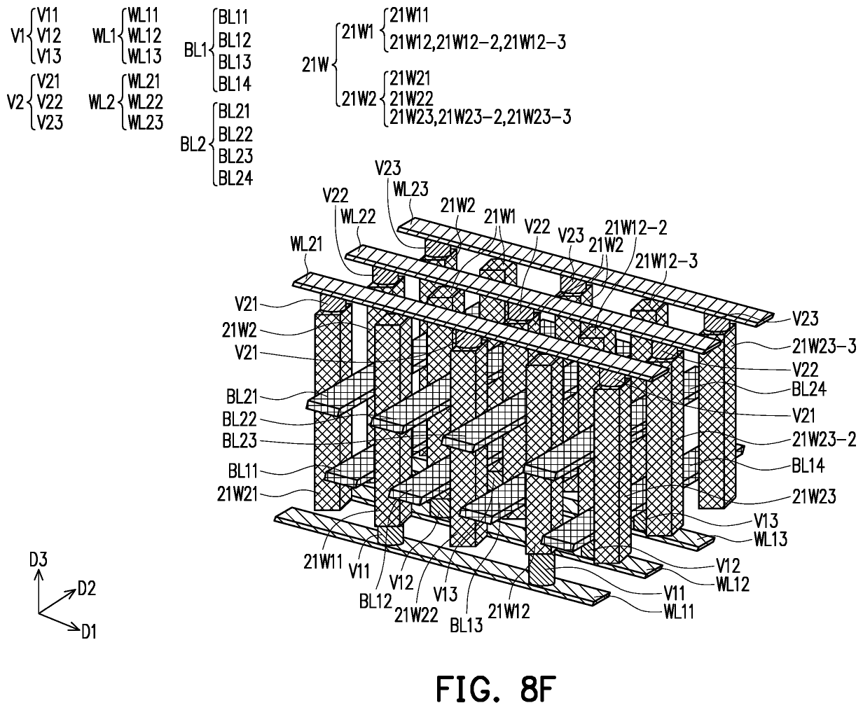

FIGS. 2A, 3A, 4A, 5A, 6A, 7A, and 8A illustrate schematic plan views of an intermediate step in the manufacture of a memory device, FIGS. 2B-2C, 3B-3C, 4B-4D, 5B-5E, 6B-6E, 7B-7E, and 8B-8E illustrate schematic cross-sectional views of an intermediate step in the manufacture of a memory device, FIG. 8F illustrates a schematic and simplified perspective view of a memory device, in accordance with some embodiments. In FIGS. 2A through 8E, figures ending with a “B” designation are illustrated along the schematic cross-section B-B shown in the corresponding figure with the “A” designation. Similarly, figures ending with a “C” designation are illustrated along the schematic cross-section C-C shown in the corresponding figure with the “A” designation. For example, FIG. 2B illustrates a cross-sectional view of the structure shown in the plan view of FIG. 2A along the cross-section 2B-2B indicated in FIG. 2A, and FIG. 2C illustrates a cross-sectional view of the structure shown in FIG. 2A along the cross-section 2C-2C indicated in FIG. 2A. Similarly, FIG. 4D illustrates a cross-sectional view of the structure shown in FIG. 4A along the cross-section 4D-4D indicated in FIG. 4A, and FIG. 5E illustrates a cross-sectional view of the structure shown in FIG. 5A along the cross-section 5E-5E indicated in FIG. 5A. For clarity of illustrations, in the following drawings are illustrated the orthogonal axes (D1, D2 and D3) according to which the views are oriented.

Referring to FIGS. 2A, 2B, and 2C and with reference to FIG. 1, a plurality of first word lines WL1 (e.g., WL11, WL12, and WL13) may be formed in a first dielectric sublayer 1261. For example, the first dielectric sublayer 1261 surrounds and isolates the first word lines WL1. The first word lines WL1 may extend in a first direction D1 which is substantially orthogonal to the third direction D3 (e.g., a thickness direction or a stacking direction of the dielectric sublayers). The first dielectric sublayer 1261 may include one or more dielectric materials such as silicon oxide, silicon nitride, silicon oxynitride, silicon carbide, high-k materials, low-k materials, the like, or combinations thereof. For example, the first dielectric sublayer 1261 is a portion of the dielectric layers 126 of the interconnect structure 120 described in FIG. 1.

In some embodiments, the first word lines WL1 are electrically connected to ones of the conductive patterns 124 by ones of the conductive vias 122. The first word lines WL1 may be formed by depositing conductive materials (e.g., titanium, titanium nitride, tantalum, tantalum nitride, ruthenium, tungsten, cobalt, aluminum, copper, alloys of these, oxides of these, the like, or combinations thereof) in the first dielectric sublayer 1261. In some embodiments, a planarization process (e.g., CMP, grinding, etching, a combination thereof, etc.) may be performed to remove excess conductive material. These and all other suitable techniques are fully intended to be within the scope of the disclosure.

The first word lines WL1 may be spaced apart from one another along the second direction D2 that is substantially orthogonal to the first direction D1. In some embodiments, adjacent two of the first word lines WL1 are separated by a first gap GW1 that is a non-zero distance measured in the second direction D2. In some embodiments, the first word lines WL1 are evenly distributed in the first dielectric sublayer 1261 and the first gap GW1 between any adjacent two of the first word lines WL1 may be substantially equal, within process variations. Alternatively, the first gaps GW1 may have different values measured in the second direction D2 based on the process and product requirements. Other shapes, dimensions, or distances are possible, and the first word lines WL1 may have a different number or arrangement than shown.

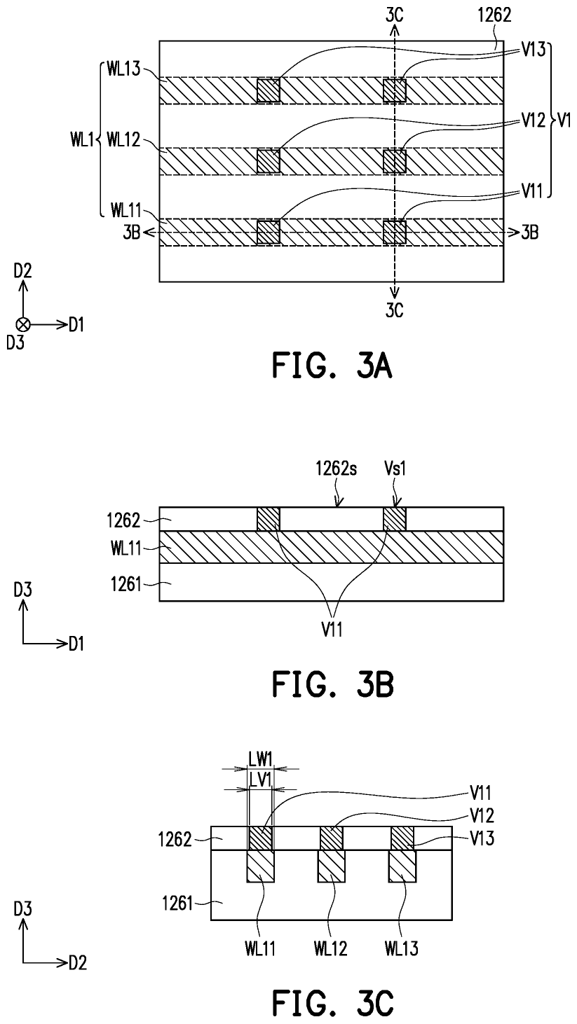

Referring to FIGS. 3A, 3B, and 3C with reference to FIGS. 2A-2C, a second dielectric sublayer 1262 may be formed on the first dielectric sublayer 1261 to cover the first word lines WL1. The second dielectric sublayer 1262 may be formed using the similar materials as the first dielectric sublayer 1261; however, any suitable dielectric materials may be utilized. In some embodiments, first conductive vias V1 (e.g., V11, V12, and V13) are formed through the second dielectric sublayer 1262 to land on and electrically connect the first word lines WL1. In some embodiments, each first word line WL1 has more than one of the first conductive vias V1 disposed thereon. The first conductive vias V1 may be formed using the materials similar to the first word lines WL1. In some embodiments, the first conductive vias V1 are formed by forming openings (not shown) in the second dielectric sublayer 1262, filling the openings with conductive materials, and performing a planarization process to remove excess conductive material. For example, the exposed surfaces Vs1 of the first conductive vias V1 are substantially leveled (or coplanar) with the surface 1262s of the second dielectric sublayer 1262, within process variations. However, any suitable materials or techniques may be utilized.

In some embodiments, the boundary of the respective first conductive via V1 is located within the boundary of the corresponding first word line WL1, in the top-down plan view. The lateral dimension of the respective first conductive via V1 may be less than (or substantially equal to) the lateral dimension of the underlying first word lines WL1. For example, as shown in the cross-section of FIG. 3C, the lateral dimension LV1 of the respective first conductive via V11 measured in the second direction D2 is less than (or substantially equal to) the lateral dimension LW1 of the underlying first word lines WL11 measured in the second direction D2, where the second direction D2 may be the widthwise direction of the first word lines WL1. In the illustrated embodiment, the first conductive vias V1 have a square (or rectangular) top-view shape. However, other top-view shapes, dimensions, thicknesses, widths, lengths, are possible, and the first conductive vias V1 may have a different number or arrangement than shown.

Referring to FIGS. 4A, 4B, 4C, and 4D with reference to FIGS. 3A-3C, a third dielectric sublayer 1263 may be formed on the second dielectric sublayer 1262. For example, the exposed surfaces Vs1 of the first conductive vias V1 and the surface 1262s of the second dielectric sublayer 1262 are physically covered by the third dielectric sublayer 1263 at this stage. The third dielectric sublayer 1263 may be formed using the similar materials as the first dielectric sublayer 1261; however, any suitable dielectric materials may be utilized. In some embodiments, a plurality of first bit lines BL1 (e.g., BL11, BL12, BL13, and BL14) is formed in the third dielectric sublayer 1263. The first bit lines BL1 may include one or more conductive materials such as tungsten, cobalt, aluminum, nickel, copper, silver, gold, alloys thereof, the like, or combinations thereof. In some embodiments, the first bit lines BL1 are formed by forming trenches in the third dielectric sublayer 1263, filling the trenches with conductive materials, and performing a planarization process to remove excess conductive material. For example, top surfaces of the first bit lines BL1 and the third dielectric sublayer 1263 are substantially leveled (or coplanar) within process variations. However, any suitable materials or techniques may be utilized.

In some embodiments, the lengthwise direction (e.g., D2) of the first bit lines BL1 is substantially orthogonal to the lengthwise direction (e.g., D1) of the first word lines WL1, in the top-down plan view. The first bit lines BL1 may be separated from one another in the first direction D1. In some embodiments, adjacent two of the first bit lines BL1 are spaced apart by a first gap GB1 which has a non-zero distance measured in the first direction D1. In some embodiments, the first bit lines BL1 are evenly distributed in the third dielectric sublayer 1263, and the first gap GB1 between any adjacent two of the first bit lines BL1 may be substantially equal, within process variations. Alternatively, the first gaps GB1 may have different values measured in the first direction D1 based on the process and product requirements.

With continued reference to FIGS. 4A-4D, a fourth dielectric sublayer 1264 may be formed on the third dielectric sublayer 1263. For example, the top surfaces of the first bit lines BL1 and the third dielectric sublayer 1263 are physically covered by the fourth dielectric sublayer 1264. The fourth dielectric sublayer 1264 may be formed using the similar materials as the first dielectric sublayer 1261; however, any suitable dielectric materials may be utilized. In some embodiments, a plurality of second bit lines BL2 (e.g., BL21, BL22, BL23, and BL24) is formed in the fourth dielectric sublayer 1264. The second bit lines BL2 may be surrounded by the fourth dielectric sublayer 1264 and physically and electrically isolated from the first bit lines BL1 by the fourth dielectric sublayer 1264. The second bit lines BL2 may include the similar material with the first bit lines BL1 and may be formed using similar techniques. For example, top surfaces of the second bit lines BL2 and the fourth dielectric sublayer 1264 are substantially leveled (or coplanar) within process variations. However, any suitable materials or techniques may be utilized.

In some embodiments, the second bit lines BL2 are substantially aligned with the first bit lines BL1 in the third direction D3, within process variations. For example, the first bit lines and the second bit lines (e.g., BL11 and BL21; BL12 and BL22; BL13 and BL23; BL14 and BL24) are vertically aligned with one another and overlap in the top-down view. In some embodiments, adjacent two of the second bit lines BL2 are spaced apart by a second gap GB2, where the second gap GB2 has a non-zero distance measured in the first direction D1. In some embodiments, the second gap GB2 is substantially equal to the underlying first gap GB1, within process variations. The second bit lines BL2 may be evenly distributed in the fourth dielectric sublayer 1264, and the second gap GB2 between any adjacent two of the second bit lines BL2 may be substantially equal, within process variations. Alternatively, the first bit lines and the second bit lines are vertically offset, and the second gaps GB2 and the underlying first gaps GB1 may have different values measured in the first direction D1 based on the process and product requirements.

Still referring to FIGS. 4A-4D, the respective first conductive via V1 may be directly underneath the first gap GB1 and the second gap GB2. The first bit lines BL1 and the second bit lines BL2 may be vertically offset from the first conductive vias V1 as shown in the cross-section of FIG. 4B. For example, the lateral dimension LV1′ of the respective first conductive via V11 measured in the first direction D1 is less than (or substantially equal to) the lateral distance of the first gap GB1 measured in the first direction D1 and/or the lateral distance of the second gap GB2 measured in the first direction D1, where the first direction D1 is the widthwise direction of the first/second bit lines BL1/BL2. Other shapes, dimensions, thicknesses, widths, lengths, or distances are possible, and the first/second bit lines BL1/BL2 may have a different number or arrangement than shown.

Referring to FIGS. 5A, 5B, 5C, 5D, and 5E with reference to FIGS. 4A-4D, a fifth dielectric sublayer 1265 may be formed on the fourth dielectric sublayer 1264. For example, the top surfaces of the second bit lines BL2 and the fourth dielectric sublayer 1264 are physically covered by the fifth dielectric sublayer 1265. The fifth dielectric sublayer 1265 may be formed using the similar materials as the first dielectric sublayer 1261; however, any suitable dielectric materials may be utilized. In some embodiments, a portion of the dielectric sublayers (e.g., the third dielectric sublayer 1263, the fourth dielectric sublayer 1264, and the fifth dielectric sublayer 1265) is removed to form a plurality of bit line stacks BLS0 (e.g., BS1, BS2, BS3, and BS4) by using suitable lithographic and etching processes or other suitable patterning process. For example, a photoresist (not illustrated) may be formed over the fifth dielectric sublayer 1265 and patterned using acceptable lithography techniques. The pattern of the photoresist may then be transferred by using one or more acceptable etching process(es) to form a plurality of holes (e.g., H11, H12, H13, H14, H15, H24, H25, H34, and H25). The etching process(es) may be anisotropic. In some embodiments, each hole penetrates through the fifth dielectric sublayer 1265, the fourth dielectric sublayer 1264, and the third dielectric sublayer 1263. The photoresist may then be removed using an ashing process or other suitable removal process.

In some embodiments, first holes (e.g., H12, H14, H24, H34) accessibly expose the surfaces Vs1 of the first conductive vias V1. For example, each of the first conductive vias V1 is accessibly exposed by one of the first holes (e.g., H12, H14, H24, H34). In the illustrated embodiment, the first conductive vias V1 are exposed by the first holes arranged along the second direction D2 (or the lengthwise direction of the first/second bit lines) and between the adjacent two of the bit line stacks (e.g., BS1 and BS2; BS3 and BS4). In some embodiments, a portion of the surface 1262s of the second dielectric sublayer 1262 surrounding the first conductive vias V1 may be accessibly exposed by the first holes (e.g., H12, H14, H24, H34). The number of the holes is greater than the number of the first conductive vias V1. For example, second holes (e.g., H11, H13, H15, H25, H35) below which the first conductive vias V1 are not formed may expose the surface 1262s of the second dielectric sublayer 1262. For example, the second holes are arranged along the second direction D2, and some of the second holes are arranged between the adjacent two of the bit line stacks (e.g., BS2 and BS3).

In some embodiments, each bit line stack (e.g., BS1) includes the first bit line (e.g., BL11) and the second bit line (e.g., BL21) formed over the first bit line (e.g., BL11). In each bit line stack BLS0, the first bit line (e.g., BL11) may be separated and isolated from the second bit line (e.g., BL21) by the fourth dielectric sublayer 1264. In some embodiments, the bit line stacks BLS0 have substantially vertical sidewalls, as shown in FIG. 5B. Alternatively, the bit line stacks BLS0 have tilt/irregular sidewalls. The respective sidewall of the bit line stack BLS0 may include sidewalls of the first and second bit lines. Adjacent bit line stacks (e.g., BS1 and BS2; BS2 and BS3; BS3 and BS4) may be separated by a lateral distance GB3 measured in the first direction D1. In some embodiments, the lateral distance GB3 is substantially equal to (or less than) the second gap GB2 and/or the first gap GB1. The lateral distance GB3 may be a first lateral dimension of the corresponding hole measured in the first direction D1. The respective hole may include a second lateral dimension GB3′ measured in the second direction D2 as shown in FIGS. 5C and 5E. The second lateral dimension GB3′ may be substantially equal to the first lateral dimension or may be different from the first lateral dimension, depending on the process and product requirements. The second lateral dimension GB3′ may be greater than (or substantially equal to) the lateral dimension of the underlying first word lines WL1 measured in the second direction D2. Alternatively, the second lateral dimension GB3′ is less than the lateral dimension of the underlying first word lines WL1 measured in the second direction D2. In the illustrated embodiment, each hole has a square (or rectangular) top-view shape. However, other top-view shapes and dimensions are possible, and the holes may have a different number or arrangement than shown.

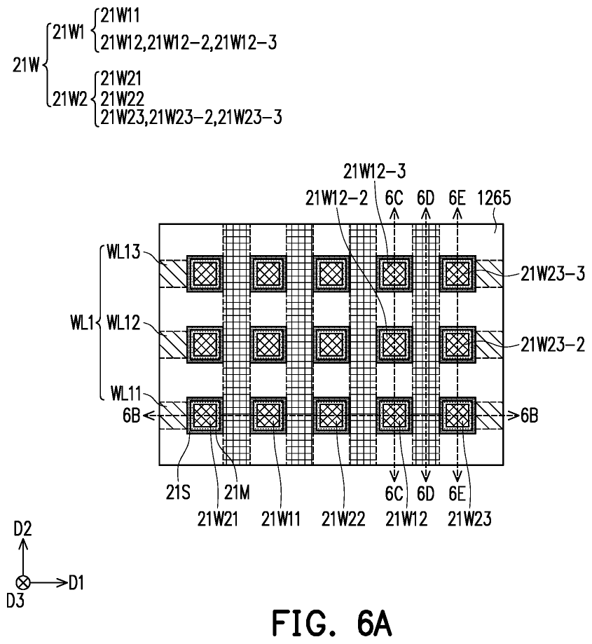

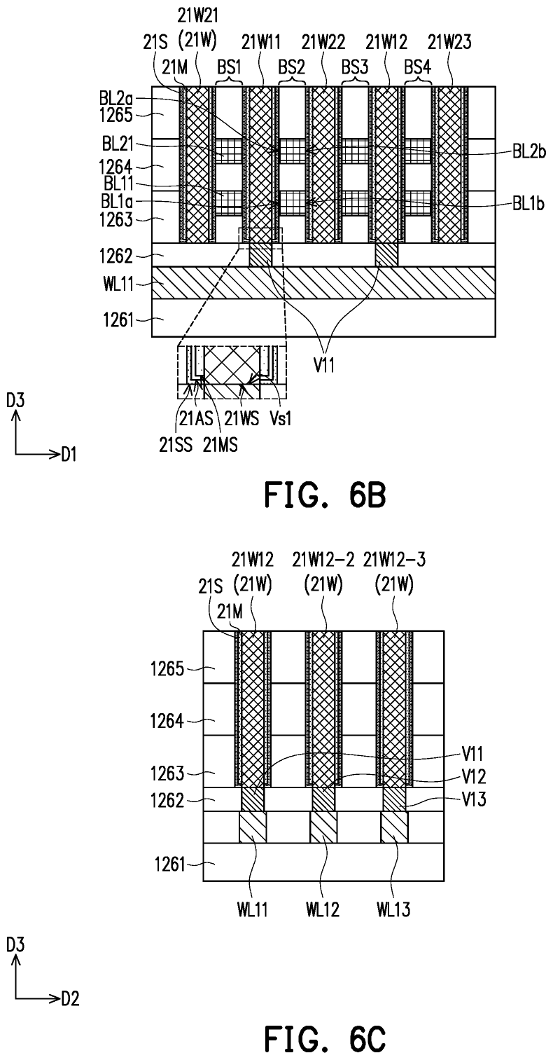

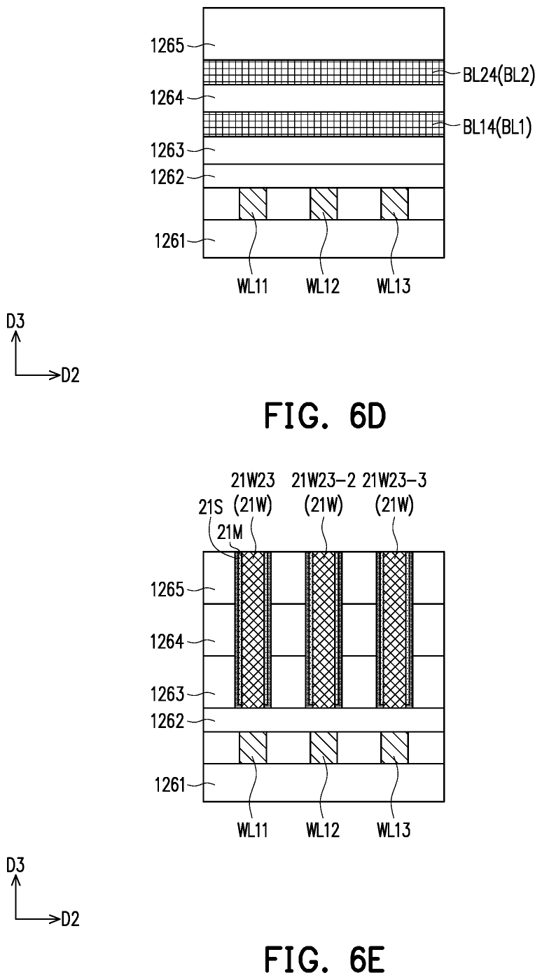

Referring to FIGS. 6A, 6B, 6C, 6D, and 6E with reference to FIGS. 5A-5E, a selector layer (or selector spacer) 21S, a memory layer (or memory spacer) 21M, and a word line column 21W may be formed in each hole (e.g., H11, H12, H13, H14, H15, H24, H25, H34, H25). In some embodiments, a selector material is conformally deposited in each hole to cover the sidewalls of each bit line stack BLS0, and then a memory material is conformally deposited on the selector material. One or more etching process(es) may be performed to remove bottom portions of the selector and memory materials, and at least the surfaces Vs1 of the first conductive vias V1 may be accessibly exposed by the selector layer 21S and the memory layer 21M. After removal of the bottom portions of the selector and memory materials, the remaining selector material forms the selector layer 21S lining opposing sides (BL1a and BL1b) of the first bit line (e.g., BL11) and opposing sides (BL2a and BL2b) of the second bit line (e.g., BL21). The selector layer 21S may have an L-shaped profile in cross-section. The bottom surface 21MS of the memory layer 21M may be disposed over the bottom surface 21SS of the selector layer 21S. One or more conductive material(s) of the word line columns 21W may be formed in the rest space of the holes to land on and electrically connect the first conductive vias V1. The bottom surface 21WS of the word line column 21W may be substantially leveled (or coplanar) with the bottom surface 21SS of the selector layer 21S, within process variations.

In some embodiments, the selector layer 21S is a material that exhibits an ovonic threshold switching (OTS) effect or similar effect. The selector material may include a binary material (e.g., SiTe, GeTe, CTe, BTe, ZnTe, AlTe, GeSe, GeSb, etc.), a ternary material (e.g., GeSeAs, GeSeSb, GeSbTe, GeSiAs, GeAsSb, etc.), a quadruple material (e.g., GeSeAsTe, GeSeTeSi, GeSeTeAs, GeTeSiAs, GeSeAsSb, etc.), and/or the like. In some embodiments, the selector layer 21S includes a chalcogenide material, a voltage conductive bridge material, or any suitable selector material. The selector layer 21S may be deposited by CVD, PVD, ALD, PECVD, or the like.

The type and physical mechanism of the memory device may depend on the particular material of the memory layer 21M. For example, the memory layer 21M is set to a particular resistance state by applying an electric field across the memory layer 21M or by heating the memory layer 21M. In some embodiments, the memory layer 21M includes a resistive memory material suitable for storing digital values (e.g., 0 or 1), such as a resistive random access memory (RRAM) material, a phase-change random access memory (PCRAM) material, a conductive bridging random access memory (CBRAM) material, or the like. In some embodiments, the memory layer 21M includes a metal oxide (e.g., HfOx, ZrOx, TiOx, NiOx, AlOx, SnOx, GdOx, IGZO, the like, or a combination thereof) or a chalcogenide material (e.g., GeS₂, GeSe, AgGeSe, GeSbTe, the like). The memory material 211 may be deposited by CVD, PVD, ALD, PECVD, or the like. These are examples, and other materials or other deposition techniques are possible, and all are also considered within the scope of the disclosure.

In some embodiments, the word line columns 21W includes one or more conductive material(s) similar to those described previously for the first word lines WL1 (see FIGS. 2A-2C). The word line columns 21W may be formed using techniques similar to those described previously for the first word lines WL1. Other materials or techniques are possible. In some embodiments, the word line columns 21W includes first word line columns 21W1 (e.g., 21W11, 21W12, 21W12-2, 21W12-3) formed in the first holes (e.g., H12, H14, H24, H34) and second word line columns 21W2 (e.g., 21W21, 21W22, 21W23, 21W23-2, 21W23-3) formed in the second holes (e.g., H11, H13, H15, H25, H35). The bottom surfaces 21WS of the first word line columns 21W1 may be in physical contact with the corresponding first conductive via V1. The bottom surfaces 21WS of the second word line columns 21W2 may be in physical contact with the second dielectric sublayer 1262. In some embodiments, a planarization process (e.g., CMP, grinding, etching, a combination thereof) may be performed to remove excess materials over the fifth dielectric layer 1265. After planarization, top surfaces of the word line columns 21W, the memory layer 21M, the selector layer 21S, and the fifth dielectric layer 1265 may be substantially leveled (or coplanar) within process variations.

With continued reference to FIG. 6B, a barrier material (and/or an adhesion material) may be conformally deposited on the selector material before depositing the memory material. In such embodiments, when removing the bottom portions of the selector and memory materials, a bottom portion of the barrier/adhesion material is also removed to form a barrier (or an adhesive) 21A between the selector layer 21S and the memory layer 21M. For example, the bottom surface 21AS of the barrier 21A is between the bottom surface 21MS of the memory layer 21M and the bottom surface 21SS of the selector layer 21S in the third direction D3. The barrier (or adhesive) 21A may include any suitable barrier material or any suitable adhesion material for improving the adhesion of the selector layer 21S and the memory layer 21M.

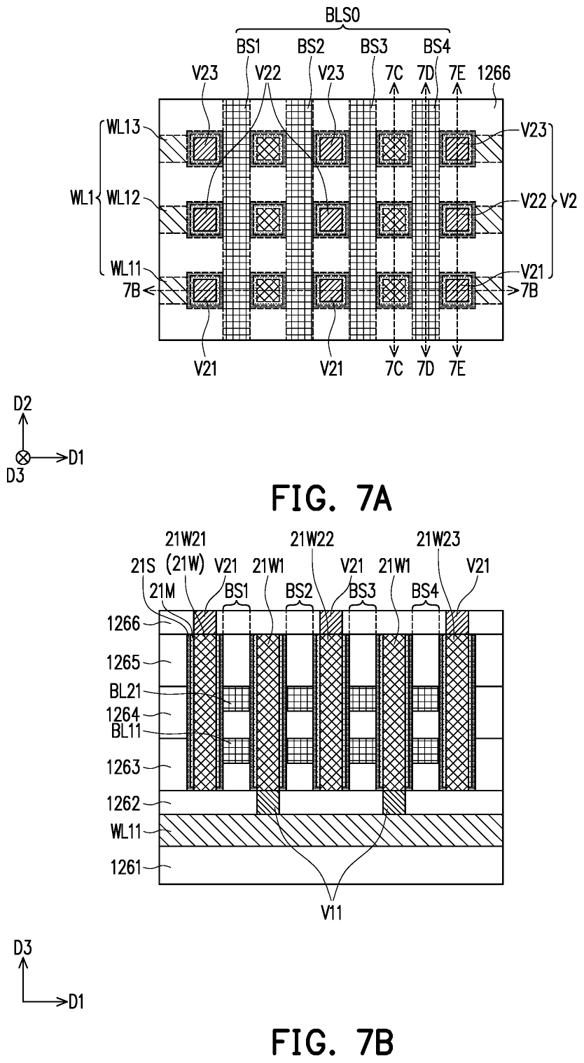

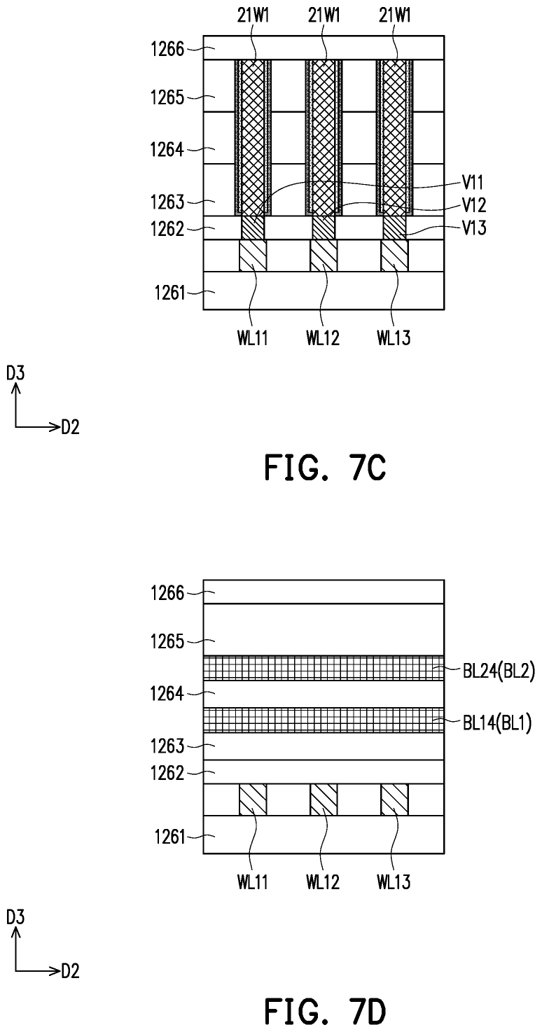

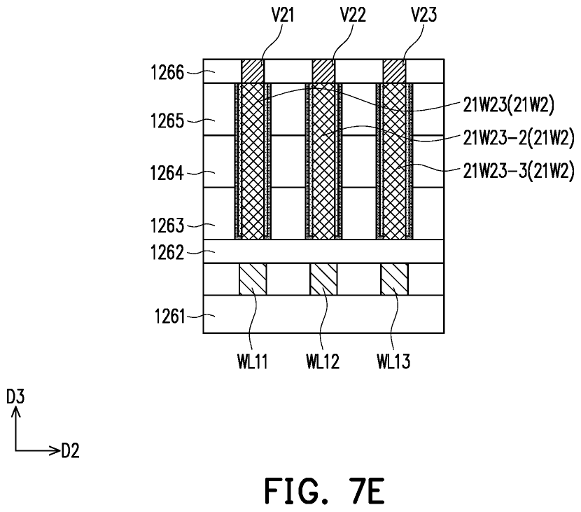

Referring to FIGS. 7A, 7B, 7C, 7D, and 7E with reference to FIGS. 6A-6E, a sixth dielectric sublayer 1266 may be formed on the fifth dielectric sublayer 1265. The sixth dielectric sublayer 1266 may be formed using the similar materials as the first dielectric sublayer 1261; however, any suitable dielectric materials may be utilized. A plurality of second conductive vias V2 (e.g., V21, V22, V23) may be formed in the sixth dielectric sublayer 1266 to land on and electrically connect the second word line columns 21W2 that are not electrically connected to the first word lines WL1. The second conductive vias V2 may be formed using the similar materials as the first conductive vias V1; however, any suitable conductive materials may be utilized. In some embodiments, a planarization process (e.g., CMP, grinding, etching, a combination thereof, etc.) may be performed to level the top surfaces of the second conductive vias V2 and the sixth dielectric sublayer 1266. In some embodiments, the top surfaces of the first word line columns 21W1 may be physically covered by the sixth dielectric sublayer 1266. The second conductive vias V2 may have lateral dimensions larger than, about the same as, or smaller than the lateral dimensions (e.g., LV1 labeled in FIG. 3C and/or LV1′ labeled in FIG. 4B) of the first conductive vias V1.

Referring to FIGS. 8A, 8B, 8C, 8D, and 8E with reference to FIGS. 7A-7E, a seventh dielectric sublayer 1267 may be formed on the sixth dielectric sublayer 1266. The seventh dielectric sublayer 1267 may be formed using the similar materials as the first dielectric sublayer 1261; however, any suitable dielectric materials may be utilized. A plurality of second word lines WL2 (e.g., WL21, WL22, WL23) may be formed in the seventh dielectric sublayer 1267 to electrically connect the second conductive vias V2. The second word lines WL2 may be formed using the similar materials as the first word lines WL1; however, any suitable conductive materials may be utilized. In some embodiments, a planarization process (e.g., CMP, grinding, etching, a combination thereof, etc.) may be performed to level the top surfaces of the second word lines WL2 and the seventh dielectric sublayer 1267. The second word line columns 21W2 may be electrically coupled to the second word lines WL2 through the second conductive vias V2. In some embodiments, the top surfaces of the first word line columns 21W1 are separated and/or isolated from the second word lines WL2 by the seventh dielectric sublayer 1267, where the first word line columns 21W1 are electrically coupled to the first word lines WL1 through the first conductive vias V1. The first word line columns 21W1 and the second word line columns 21W2 may be interleaved with one another in the cross section shown in FIG. 8B, where one of the bit line stacks BLS0 (e.g., BS1, BS2, BS3, and BS4) is laterally interposed between the adjacent two of the first word line columns 21W1 and the second word line columns 21W2.

The structures shown in FIGS. 8A-8E may be viewed as a memory device 140-1. The memory device 140-1 includes a plurality of memory cells MC0 (e.g., MC11, MC12, MC21, MC22; shown as dashed boxes in FIG. 8B) arranged in an array of rows and columns to form a three-dimensional memory array. For example, the memory cells (MC21 and MC22) are above and overlap the memory ells (MC11 and MC12), respectively. The memory cells (MC11 and MC21) may include different regions of the same layers of the memory layer 21M and the selector layer 21S formed on the one side, and the memory cells (MC12 and MC22) may include different regions of the same layers of the memory layer 21M and the selector layer 21S formed on another side. The first and second word lines (WL1 and WL2) may be formed as two separate layers above and below the word line columns 21W. In this manner, the first word line (e.g., W11) may control the memory cells (MC12 and MC22) located on one sides (e.g., BL1b and BL2B) of the first/second bit lines (BL11/BL21), and the second word line (e.g., WL21) may control the memory cells (MC11 and MC21) located on the opposing sides (e.g., BL1a and BL2a) of the bit lines first/second bit lines (BL11/BL21).

Read and write operations may be performed on each of the memory cells MC0 independently. For example, the read and write operations are performed on the memory cell MC11 using the first bit line BL11, the second word line WL21, the second word line column 21W2 through the second conductive via V21. This may allow the operations to be performed on the memory cell MC11 independently of the adjacent memory cells (e.g., MC12, MC21, MC22). Similarly, the read and write operations may be performed on the memory cell MC12 using the first bit line BL11, the first word line WL11, the first word line column 21W1 through the first conductive via V11. The read and write operations may be performed on the memory cell MC21 using the second bit line BL21, the second word line WL21, the second word line column 21W2 through the second conductive via V21. The read and write operations may be performed on the memory cell MC22 using the second bit line BL21, the first word line WL11, the first word line column 21W1 through the first conductive via V11. In this manner, any memory cell MC0 of the memory array may be controlled by biasing the corresponding first/second bit line (e.g., BL11/BL21) and corresponding first/second word line (e.g., WL11/WL21). By configuring the vertically overlapping first/second bit lines (BL1/BL2) with a first word line column 21W1 shared on one side of the first/second bit lines (BL1/BL2) and a second word line column 21W2 shared on the opposing side of the first/second bit lines (BL1/BL2), the number of the memory cells MC0 may be doubled within the same area without an area penalty and without the use of dummy cells.

Referring to FIG. 8F and with reference to FIGS. 8A-8E, the structure shown in FIG. 8F is a simplified perspective view of the memory device 140-1, where only first/second word lines (WL1/WL2), first/second bit lines (BL1/BL2), first/second conductive vias (V1/V2), and word line columns 21W are illustrated for the ease of description. In some embodiments, the first word lines WL1 and the second word lines WL2 are parallel and arranged in different layers, and the first/second bit lines BL1/BL2 are perpendicular to the first/second word lines WL1/WL2. The first word line columns 21W1 (e.g., 21W11, 21W12) may be electrically coupled to the same first word line (e.g., W11) through the first conductive vias V11, and the second word line columns 21W2 (e.g., 21W21, 21W22, 21W23) may be electrically coupled to the same second word line (e.g., W21) through the second conductive vias V21. The first word line columns (e.g., 21W11, 21W12) connected to the first conductive vias V11 and the second word line columns (e.g., 21W21, 21W22, 21W23) connected to the second conductive vias V21 may be alternately arranged along the first direction D1.

The second word line columns 21W2 (e.g., 21W23, 21W23-2, 21W23-3) arranged along the second direction D2 may be connected to the second word lines WL2 through the second conductive vias V2 in a one-to-one correspondence. For example, the second word line column 21W23 is connected to the second word line WL21 through the second conductive via V21, the second word line column 21W23-2 is connected to the second word line WL22 through the second conductive via V22, and the word line column 21W23-3 is connected to the second word line WL23 through the second conductive via V23. Similarly, the first word line columns 21W1 (e.g., 21W12, 21W12-2, 21W12-3) arranged along the second direction D2 may be connected to the first word lines WL1 through the first conductive vias V1 in a one-to-one correspondence. For example, the first word line column 21W12 is connected to the first word line WL11 through the first conductive via V11, the first word line column 21W12-2 is connected to the first word line WL12 through the first conductive via V12, and the first word line column 21W12-3 is connected to the first word line WL13 through the first conductive via V13.

FIG. 9A illustrates a schematic plan view of a memory device, FIGS. 9B-9E illustrate schematic cross-sectional views of a memory device, and FIG. 9F illustrates a schematic and simplified perspective view of a memory device, in accordance with some embodiments. FIGS. 9B, 9C, 9D, and 9E are illustrated along the schematic cross-sections 9B-9B, 9C-9C, 9D-9D, and 9E-9E shown in FIG. 9A, respectively. The structure shown in FIG. 9F is a simplified perspective view of the memory device, where only first/second word lines (WL1/WL2), first/second bit lines (BL1/BL2), first/second conductive vias (V1′/V2′), and word line columns 21W are illustrated for the ease of description. Unless specified otherwise, like reference numerals in the present embodiment represent like components in the embodiment shown in FIGS. 2A-8F. Although method embodiments are discussed as being performed in a particular order, other embodiments may be performed in any logical order.

Referring to FIGS. 9A-9F and with reference to FIGS. 8A-8F, various views of a memory device 140-2 are provided in FIGS. 9A-9F. The difference between the memory device 140-2 and the memory device 140-1 described in FIGS. 8A-8F lies in the configuration of the first and second vias (V1′ and V2′). For example, the first word line columns 21W1 (e.g., 21W11, 21W12, 21W13, 21W11-2, 21W13-2) are physically and electrically connected to the first word lines WL1 (e.g., WL11, WL12, WL13) through the first conductive vias V1′ (e.g., V11′ V12, V13′), and the first word line columns 21W1 are isolated from the second word lines WL2 through the sixth dielectric sublayer 1266. The second word line columns 21W2 (e.g., 21W21, 21W22, 21W23, 21W21-2) may be physically and electrically connected to the second word lines WL2 (e.g., WL21, WL22, WL23) through the second conductive vias V2′ (e.g., V21′ V22, V23′), and the second word line columns 21W2 may be isolated from the first word lines WL1 through the second dielectric sublayer 1262. The first and second vias (V1′ and V2′) may be alternately arranged in the first direction D1 and the second direction D2, thereby forming a checkerboard pattern matrix in the top-down plan view.

With continued reference to FIG. 9B, the memory device 140-2 may include the memory cells MC0 (e.g., MC11, MC12, MC21, MC22) arranged in an array of rows and columns to form a three-dimensional memory array, where the memory cells MC0 may be independently controlled using corresponding first/second bit lines (BL1/BL2) and the first/second word lines (WL1/WL2). In some embodiments, the first word line W11 may control the memory cells (MC12 and MC22) located on one sides (e.g., BL1a and BL2a) of the first/second bit lines (BL11/BL21), and the second word line (e.g., WL21) may control the memory cells (MC11 and MC21) located on the opposing sides (e.g., BL1b and BL2b) of the bit lines first/second bit lines (BL11/BL21).

With continued reference to FIGS. 9B, 9C, 9E and 9F, the first word line columns 21W1 connected to the first conductive vias V1′ and the second word line columns 21W2 connected to the second conductive vias V2′ may be alternately arranged along the first direction D1 and the second direction D2. For example, as shown in FIGS. 9B and 9F, the first word line columns (21W11 and 21W13) are coupled to the first word line WL11 through the first conductive vias V11′, and the second word line column 21W21 arranged between the first word line columns (21W11 and 21W13) in the first direction D1 is coupled to the second word line WL21 through the second conductive via V21′. As shown in FIGS. 9C and 9F, the second word line columns (21W21 and 21W21-2) may be coupled to the second word lines (WL21 and WL23) through the second conductive vias (V21′ and V23′), respectively. The first word line column 21W12 arranged between the second word line columns (21W21 and 21W21-2) in the second direction D2 may be coupled to the first word line WL12 through the first conductive via V12′. As shown in FIGS. 9E and 9F, the first word line columns (21W13 and 21W13-2) may be coupled to the first word lines (WL11 and WL13) through the first conductive vias (V11′ and V13′), respectively. The second word line column 21W23 arranged between the first word line columns (21W13 and 21W13-2) in the second direction D2 may be coupled to the second word line WL22 through the second conductive via V22′.

The memory device 140-2 may include the vertically overlapping first/second bit lines (BL1/BL2) with a first word line column 21W1 shared on one side of the first/second bit lines (BL1/BL2) and a second word line column 21W2 shared on the opposing side of the first/second bit lines (BL1/BL2). The memory device 140-2 includes the first/second word lines (WL1/WL2) disposed in separate dielectric sublayers through first/second conductive vias (V1′ and V2′) and the first/second word line columns (21W1/21W2) interleaved with one another in both of the first/second directions (D1/D2). In such configuration, the number of the memory cells MC0 may be doubled within the same area without an area penalty.

According to some embodiments, a device includes: a first word line and a second word line disposed over the first word line, the first and second word lines extending in a first direction; a first bit line between the first and second word lines and extending a second direction; a first word line column disposed on a first side of the first bit line and extending in a third direction, the first word line column being coupled to the first word line through a first conductive via, wherein the first, second, and third directions are different; a second word line column extending in the third direction and disposed on a second side of the first bit line opposite to the first side, the second word line column being coupled to the second word line through a second conductive via, wherein the first and second conductive vias are offset in the first and third direction; a selector layer lining the first and second sides of the first bit line; and a memory layer lining the selector layer and connected to the first and second word line columns.

According to some alternative embodiments, a device includes: a first word line and a second word line separated from the first word line, the first word line overlapping the second word line in a top-down view; a first bit line between the first and second word lines, the first bit line intersecting the first and second word lines in the top-down view; a first word line column and a second word line column disposed on a first side and a second side of the first bit line, respectively, wherein the first and second word line columns overlap the first and second word lines in the top-down view; a first conductive via disposed between and electrically coupled to the first word line and the first word line column; a second conductive via disposed between and electrically coupled to the second word line and the second word line column, the first and second conductive vias being laterally offset in the top-down view; a selector layer lining the first and second sides of the first bit line; and a memory layer lining the selector layer and connected to the first and second word line columns.

According to some alternative embodiments, a method includes: forming a first conductive via on a first word line; forming a first bit line over the first conductive via, wherein the first word line extends in a first direction, the first bit line extends in a second direction different from the first direction; forming a selector spacer on two opposing sides of the first bit line; forming a memory spacer on the selector spacer; forming a first word line column and a second word line column in a third direction, wherein the memory spacer lines the first and second word line columns, the first word line column lands on the first conductive via, and the third direction is different from the first and second directions; forming a second conductive via on the second word line column; and forming a second word line on the second conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first word line and a second word line disposed over the first word line, the first and second word lines extending in a first direction;
a first bit line between the first and second word lines and extending a second direction;
a first word line column disposed on a first side of the first bit line and extending in a third direction, the first word line column being coupled to the first word line through a first conductive via, wherein the first, second, and third directions are different;
a second word line column extending in the third direction and disposed on a second side of the first bit line opposite to the first side, the second word line column being coupled to the second word line through a second conductive via, wherein the first and second conductive vias are offset in the first and third direction;
a selector layer lining the first and second sides of the first bit line; and
a memory layer lining the selector layer and connected to the first and second word line columns.

2. The device of claim 1, further comprising:
a second bit line disposed over the first bit line in the third direction and interposed between the first and second word line columns in the first direction, and the selector layer lining the second bit line.

3. The device of claim 1, wherein the first and second conductive vias are offset in the second direction.

4. The device of claim 1, wherein the first word line column is separated from the second word line in the third direction by a dielectric layer, and the second conductive via is laterally covered by the dielectric layer.

5. The device of claim 1, wherein the second word line column is separated from the first word line in the third direction by a dielectric layer, and the first conductive via is laterally covered by the dielectric layer.

6. The device of claim 1, further comprising:
a first memory cell comprising a portion of the first bit line, a portion of the first word line column connected to the first word line through the first conductive via, a portion of the selector layer, and a portion of the memory layer; and
a second memory cell disposed alongside the first memory cell in the first direction, the second memory cell comprising another portion of the first bit line, a portion of the second word line column connected to the second word line through the second conductive via, another portion of the selector layer, and another portion of the memory layer.

7. The device of claim 1, further comprising:
additional first word line extending in the first direction and separated from the first word line in the second direction; and
additional first word line column coupled to the additional first word line through additional first conductive via, wherein the additional first word line column and the first word line column are arranged in the second direction.

8. The device of claim 1, further comprising:
additional second word line extending in the first direction and separated from the second word line in the second direction; and
additional second word line column coupled to the additional second word line through additional second conductive via, wherein the additional second word line column and the second word line column are arranged in the second direction.

9. The device of claim 1, further comprising:
additional first word line extending in the first direction; and
additional first word line column coupled to the additional first word line through additional first conductive via, wherein the additional first word line column is offset from the first word line column in the first and second directions.

10. The device of claim 1, further comprising:
additional second word line extending in the first direction; and
additional second word line column coupled to the additional second word line through additional second conductive via, wherein the additional second word line column is offset from the second word line column in the first and second directions.

11. A device, comprising:
a first word line and a second word line separated from the first word line, the first word line overlapping the second word line in a top-down view;
a first bit line between the first and second word lines, the first bit line intersecting the first and second word lines in the top-down view;
a first word line column and a second word line column disposed on a first side and a second side of the first bit line, respectively, wherein the first and second word line columns overlap the first and second word lines in the top-down view;
a first conductive via disposed between and electrically coupled to the first word line and the first word line column;
a second conductive via disposed between and electrically coupled to the second word line and the second word line column, the first and second conductive vias being laterally offset in the top-down view;
a selector layer lining the first and second sides of the first bit line; and
a memory layer lining the selector layer and connected to the first and second word line columns.

12. The device of claim 11, further comprising:
a second bit line disposed between the first bit line and the second word line, the first and second word line columns being disposed at two opposing sides of the second bit line, and the selector layer lining the two opposing sides of the second bit line.

13. The device of claim 11, wherein bottom surfaces of the selector layer and the first word line column are substantially level, the bottom surface of the first word line column is in contact with the first conductive via, and a bottom surface of the memory layer is above the bottom surface of the selector layer.

14. The device of claim 11, further comprising:
additional first word line disposed parallel to the first word line;
additional second word line disposed parallel to the second word line, the additional first word line overlapping the additional second word line in the top-down view;
additional first word line column disposed between the additional first and second word lines, the additional first word line column being disposed on the first side of the first bit line; and
additional second conductive via connected to the additional second word line column and the additional second word line.

15. The device of claim 11, further comprising:
additional first word line disposed parallel to the first word line;
additional second word line disposed parallel to the second word line, the additional first word line overlapping the additional second word line in the top-down view;
additional second word line column disposed between the additional first and second word lines, the additional second word line column being disposed on the first side of the first bit line; and
additional second conductive via connected to the additional second word line column and the additional second word line.

16. A method, comprising:
forming a first conductive via on a first word line;
forming a first bit line over the first conductive via, wherein the first word line extends in a first direction, the first bit line extends in a second direction different from the first direction;
forming a selector spacer on two opposing sides of the first bit line;
forming a memory spacer on the selector spacer;
forming a first word line column and a second word line column in a third direction, wherein the memory spacer lines the first and second word line columns, the first word line column lands on the first conductive via, and the third direction is different from the first and second directions;
forming a second conductive via on the second word line column; and
forming a second word line on the second conductive via.

17. The method of claim 16, further comprising:
forming a dielectric layer on the first word line; and
forming the first conductive via in the dielectric layer, wherein after forming the second word line column, the second word line column is isolated from the first word line through the dielectric layer.

18. The method of claim 16, further comprising:
forming a dielectric layer on the first and second word line column; and
forming the second conductive via in the dielectric layer, wherein after forming the second word line, the first word line column is isolated from the second word line through the dielectric layer.

19. The method of claim 16, further comprising:
forming a dielectric layer on the first bit line before forming the first and second word line columns; and
forming a second bit line on the dielectric layer, wherein the second bit line overlaps the first bit line in a top-down view.

20. The method of claim 16, wherein forming the first and second conductive vias comprise:
forming the first and second conductive vias in a checkerboard pattern matrix in a plan view.
